(19) United States
(12) Patent Application Publication
(10) Pub. No.: US 2026/0164630 A1
(43) Pub. Date: Jun. 11, 2026

(54) SOLDER STENCIL DESIGN WITH INSPECTION-BASED FEEDBACK

(71) Applicant: Siemens Industry Software Inc., Plano, TX (US)

(72) Inventors: Mika Holappa, Raisio (FI); Jari Soltin, Vahto (FI)

(73) Assignee: Siemens Industry Software Inc., Plano, FL (US)

(21) Appl. No.: 18/708,026

(22) PCT Filed: Nov. 29, 2021
(86) PCT No.: PCT/US2021/060982

§ 371 Date: May 7, 2024

(51) Int. Cl. H05K 13/08; H05K 3/12

(52) U.S. Cl. CPC H05K 13/0817; H05K 3/1225; H05K 2203/163

(57) ABSTRACT

This application discloses a computing system to receive measurements of solder paste disposed on a printed circuit board using a solder paste stencil, and correlate the measurements of the solder paste disposed on the printed circuit board to a solder stencil design describing the solder paste stencil utilized during an application of the solder paste on the printed circuit board. The computing system can correlate the solder paste measurements to the solder stencil design by determining a transfer efficiency of the solder paste on the printed circuit board based, at least in part, on the solder paste stencil and the measurements of the solder paste disposed on the printed circuit board. The computing system can detect a cause of a production defect associated with the printed circuit board based, at least in part, on the transfer efficiency of the solder paste on the printed circuit board.

### TECHNICAL FIELD

This application is generally related to electronic design automation and, more specifically, to solder stencil design with inspection-based feedback.

### BACKGROUND

Manufacturing of printed circuit board assemblies (PCBAs) typically begins with a bare printed circuit board (PCB), which can be populated with electronic components utilizing a variety of technologies, such as through-hole technology, surface-mount technology (SMT), or the like. With through-hole technology, lead or pins of the electronic components can be placed in holes surrounded by conductive pads and then soldered in place. With surface-mount technology, the electronic components can be placed on the printed circuit board so that the pins line up with the conductive pads or lands on the surfaces of the printed circuit board having been covered with solder paste. The solder paste, when heated, can solder the pins of electronic components to the pads or lands. The printed circuit boards populated with electronic components can be visually inspected, tested, and possibly reworked, to complete the manufacturing of the printed circuit board assemblies. The manufactured printed circuit board assemblies also may be combined with other manufactured electronic devices and/or mounted into a mechanical enclosure or product housing.

Many manufacturers of the printed circuit board assemblies utilize surface-mount technology implement a screen printing process, which disposes solder paste onto the pads or lands, for example, by applying solder paste over a stencil having apertures or holes co-located with the pads or lands of the printed circuit board. After the stencil has been separated from the printed circuit board, the solder paste applied into the apertures of the stencil can remain on the pads or lands of the printed circuit board. In practice, the location and quantity of solder paste printed on the printed circuit board can vary based on a type of solder paste, a thickness of the stencil, a shape of the apertures in the stencil, various printing parameters, such as print pressure, print speed, separation speed of the stencil from the printed circuit board, or the like. Since the location and quantity of the solder paste printed on the printed circuit board directly correlates to defects in the resulting printed circuit board assemblies, trade organizations, such as the Institute of Printed Circuits (IPC), have standards for stencils including generic Key Performance Indicators (KPIs), such as aspect ratio of apertures, area ratio of apertures, or the like, to aid in stencil design. Often, however, the stencil designs that conform to the standards and associated generic KPIs, do not work in real production, leading to manufacturing related defects due to solder paste application, which often leaves manufacturers having to undertake a time-consuming defect investigation in the printed circuit board assembly.

### SUMMARY

This application discloses a computing system to receive measurements of solder paste disposed on a printed circuit board using a solder paste stencil, and correlate the measurements of the solder paste disposed on the printed circuit board to a solder stencil design describing the solder paste stencil utilized during an application of the solder paste on the printed circuit board. The computing system can correlate the solder paste measurements to the solder stencil design by determining a transfer efficiency or offset of the solder paste on the printed circuit board based, at least in part, on the solder paste stencil and the measurements of the solder paste disposed on the printed circuit board. In some embodiments, the determination of the transfer efficiency can be performed by estimating a volume of the solder paste capable of being disposed on the printed circuit board based, at least in part, on sizes of apertures in the solder stencil design, and comparing the estimated volume of the solder paste capable of being disposed on the printed circuit board against a measured volume of the solder paste disposed on the printed circuit board to determine the transfer efficiency of the solder paste on the printed circuit board.

The computing system can detect a cause of a production defect associated with the printed circuit board based, at least in part, on the transfer efficiency or offset of the solder paste on the printed circuit board. The computing system can detect the cause of the production defect associated with the printed circuit board by determining a configuration of one or more apertures in the solder stencil design corresponds to the cause of the production defect based, at least in part, on the transfer efficiency of the solder paste on the printed circuit board. The computing system can determine one or more modifications for the solder stencil design based, at least in part, on the transfer efficiency or offset of the solder paste on the printed circuit board. The computing system can detect the cause of the production defect associated with the printed circuit board by determining a manufacturing variable corresponds to the cause of the production defect based, at least in part, on the correlation of the measurements of the solder paste disposed on the printed circuit board to the solder stencil design. Embodiments will be described below in greater detail.

### DESCRIPTION OF THE DRAWINGS

FIGS. 1 and 2 illustrate an example of a computer system of the type that may be used to implement various embodiments.

FIG. 3 illustrates an example of manufacturing system for printed circuit board assemblies with a solder stencil system with inspection-based feedback according to various embodiment

FIGS. 4A-4C illustrates an example application of solder paste onto a printed circuit board according to various embodiments.

FIG. 5 illustrates a flowchart showing an example implementation of a solder paste application with inspection-based feedback according to various embodiments.

### DETAILED DESCRIPTION

### Illustrative Operating Environment

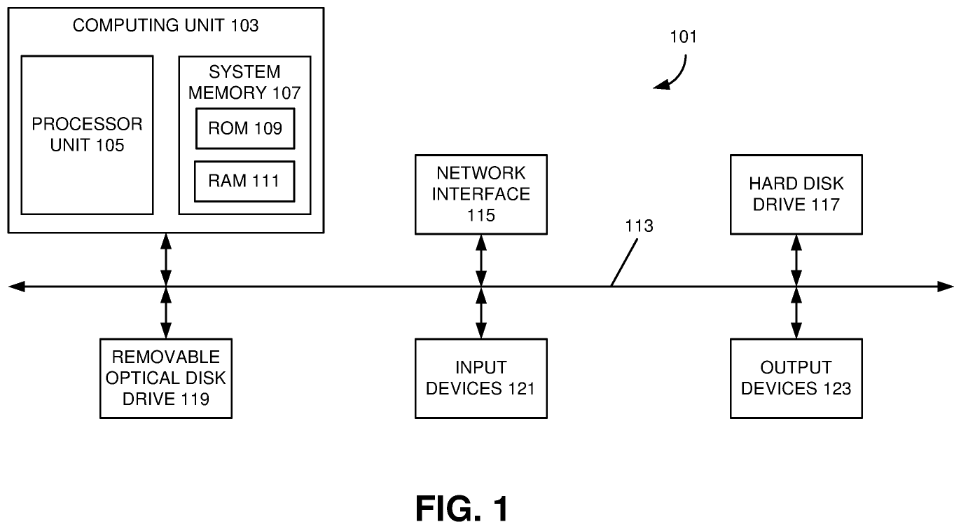

Various embodiments may be implemented through the execution of software instructions by a computing device 101, such as a programmable computer. Accordingly, FIG. 1 shows an illustrative example of a computing device 101. As seen in this figure, the computing device 101 includes a computing unit 103 with a processing unit 105 and a system memory 107. The processing unit 105 may be any type of programmable electronic device for executing software instructions, but will conventionally be a microprocessor. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processing unit 105.

The processing unit 105 and the system memory 107 are connected, either directly or indirectly, through a bus 113 or alternate communication structure, to one or more peripheral devices 115-123. For example, the processing unit 105 or the system memory 107 may be directly or indirectly connected to one or more additional memory storage devices, such as a hard disk drive 117, which can be magnetic and/or removable, a removable optical disk drive 119, and/or a flash memory card. The processing unit 105 and the system memory 107 also may be directly or indirectly connected to one or more input devices 121 and one or more output devices 123. The input devices 121 may include, for example, a keyboard, a pointing device (such as a mouse, touchpad, stylus, trackball, or joystick), a scanner, a camera, and a microphone. The output devices 123 may include, for example, a monitor display, a printer and speakers. With various examples of the computing device 101, one or more of the peripheral devices 115-123 may be internally housed with the computing unit 103. Alternately, one or more of the peripheral devices 115-123 may be external to the housing for the computing unit 103 and connected to the bus 113 through, for example, a Universal Serial Bus (USB) connection.

With some implementations, the computing unit 103 may be directly or indirectly connected to a network interface 115 for communicating with other devices making up a network interface 115 can translate data and control signals from the computing unit 103 into network messages according to one or more communication protocols, such as the transmission control protocol (TCP) and the Internet protocol (IP). Also, the network interface 115 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computing device 101 is illustrated as an example only, and it not intended to be limiting. Various embodiments may be implemented using one or more computing devices that include the components of the computing device 101 illustrated in FIG. 1, which include only a subset of the components illustrated in FIG. 1, or which include an alternate combination of components, including components that are not shown in FIG. 1. For example, various embodiments may be implemented using a multi-processor computer, a plurality of single and/or multiprocessor computers arranged into a network, or some combination of both.

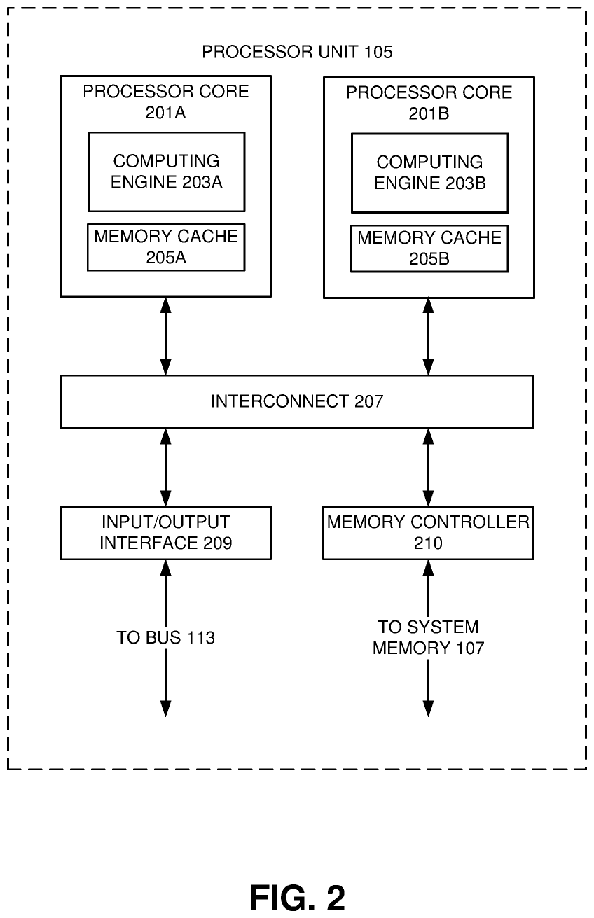

With some implementations, the processor unit 105 can have more than one processor core. Accordingly, FIG. 2 illustrates an example of a multi-core processor unit 105 that may be employed with various embodiments. As seen in this figure, the processor unit 105 includes a plurality of processor cores 201A and 201B. Each processor core 201A and 201B includes a computing engine 203A and 203B, respectively, and a memory cache 205A and 205B, respectively. As known to those of ordinary skill in the art, a computing engine 203A and 203B can include logic devices for performing various computing functions such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203A and 203B may then use its corresponding memory cache 205A and 205B, respectively, to quickly store and retrieve data and/or instructions for execution.

Each processor core 201A and 201B is connected to an interconnect 207. The particular construction of the interconnect 207 may vary depending upon the architecture of the processor unit 105. With some processor cores 201A and 201B, such as the Cell microprocessor created by Sony Corporation, Toshiba Corporation and IBM Corporation, the interconnect 207 may be implemented as an interconnect bus. With other processor units 201A and 201B, however, such as the Opteron™ and Athlon™ dual-core processors available from Advanced Micro Devices of Sunnyvale, California, the interconnect 207 may be implemented as a system request interface device. In any case, the processor cores 201A and 201B communicate through the interconnect 207 with an input/output interface 209 and a memory controller 210. The input/output interface 209 provides a communication interface to the bus 113. Similarly, the memory controller 210 controls the exchange of information to the system memory 107. With some implementations, the processor unit 105 may include additional components, such as a high-level cache memory accessible shared by the processor cores 201A and 201B. It also should be appreciated that the description of the computer network illustrated in FIG. 1 and FIG. 2 is provided as an example only, and is not intended to suggest any limitation as to the scope of use or functionality of alternate embodiments.

### Solder Stencil Design With Inspection-Based Feedback

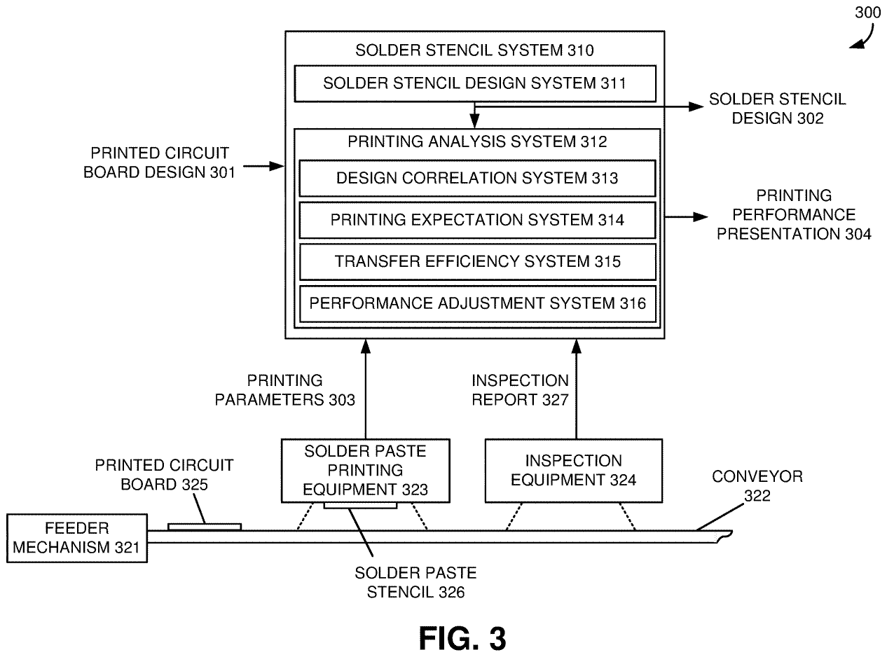

FIG. 3 illustrates an example of manufacturing system 300 for printed circuit board assemblies with a solder stencil system 310 with inspection-based feedback according to various embodiments. Referring to FIG. 3, the manufacturing system 300 can include various pieces of the assembly equipment to at least partially automate manufacture and testing of printed circuit board assemblies. In the instant example, the assembly equipment can include a feeder mechanism 321, a conveyor 322, solder paste printing equipment 323, and inspection equipment 324.

The feeder mechanism 321 can provide a printed circuit board 325 to the conveyor 322, which can move the printed circuit board 325 to the solder paste printing equipment 323. The solder paste printing equipment 323 can apply solder paste to the printed circuit board 325 utilizing a solder paste stencil 326. For example, the solder paste printing equipment 323 can utilize a screen printing process to dispose solder paste on the solder paste stencil 326 having apertures or holes allowing applied solder paste to the contact the printed circuit board 325. The solder paste printing equipment 323 can remove the solder paste stencil 326 from the printed circuit board 325, which can leave behind the solder paste having been applied through the apertures and contacting the printed circuit board 325. The solder paste printing equipment 323 can have a variety of printing parameters 303, such as a type of solder paste applied, a thickness of the solder paste stencil 326, a pressure applied during the screen printing process, a speed of the screen printing process, a removal speed for the solder paste stencil 326, support of the printed circuit board 325 by the conveyor 322, or the like. The solder paste printing equipment 323 can output the printing parameters 303 to the solder stencil system 310.

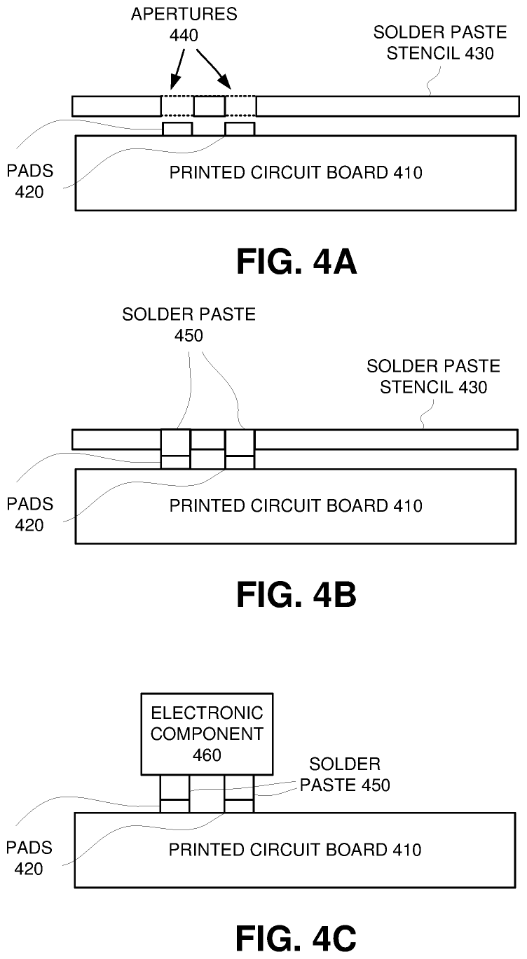

The conveyor 322 can route the printed circuit board 325 from the solder paste printing equipment 323 to inspection equipment 324, for example, to inspect the solder paste disposed on the printed circuit board 325 by the solder paste printing equipment 323. In some embodiments, the inspection equipment 324 can capture an image of the printed circuit board 325 and measure a size, volume, and/or location of the solder paste disposed on the printed circuit board 325. The inspection equipment 325 can generate an inspection report 327 describing the measurements of the solder paste disposed on the printed circuit board 325 relative to the locations of the pads or lands of the printed circuit board 325. The conveyor 222 can route the printed circuit board 325 away from the inspection equipment 324 towards other portions of the manufacturing line, which can place an electronic component on the pads and lands of the printed circuit board 325 covered with solder paste. The printed circuit board 325 also can be heated, which can allow the solder paste to connect the electronic component to printed circuit board 325. Embodiments of soldering electronic components to a printed circuit board using solder paste disposed through a solder paste stencil will be described below in FIGS. 4A-4C.

FIGS. 4A-4C illustrates an example application of solder paste onto a printed circuit board according to various embodiments. Referring to FIGS. 4A-4C, a printed circuit board 410 can include pads 420 configured to be soldered to electronic components 460 using solder paste 450. The solder paste 450 can be disposed on the pads 420 of the printed circuit board 410 using a solder paste stencil 430 positioned over the printed circuit board 410. The solder paste stencil 430 includes apertures 440 co-located with the pads 420 of the printed circuit board 410. The solder paste 450 can be printed onto the printed circuit board 410 via the solder paste stencil 430. For example, the solder paste 450 can be applied into the apertures 440 in a screen printing process, and then the solder paste stencil 430 can be separated from the printed circuit board 410, leaving behind the solder paste 450 disposed over the pads 420 of the printed circuit board 410. The electronic component 460 can be placed on the solder paste 450, which can subsequently be heated to solder the electronic component 460 to the pads 420 of the printed circuit board 410.

Referring back to FIG. 3, the solder stencil system 310 can receive a printed circuit board design 301 describing a printed circuit board assembly (PCBA) including the printed circuit board 325 populated with electronic components. In some embodiments, the printed circuit board design 301 can be specified in an Open Database ++(ODB++) format, Gerber format, or the like.

The solder stencil system 310 can include a solder stencil design system 311 to generate a solder stencil design 302 describing a characteristics of the solder paste stencil 326, such as size, thickness, stencil technology or material, an aperture configuration, or the like, based, at least in part, on the printed circuit board design 301 and the printing parameters 303. In some embodiments, a description of pads or lands on the printed circuit board 325 in the printed circuit board design 301 and possibly key performance indicators (KPIs) can be utilized by the solder stencil design system 311 to determine locations and sizing of the apertures in the solder stencil design 302. Although FIG. 3 shows the solder stencil system 310 including the solder stencil design system 311, in some embodiments, the solder stencil design system 311 can be located external to the solder stencil system 310

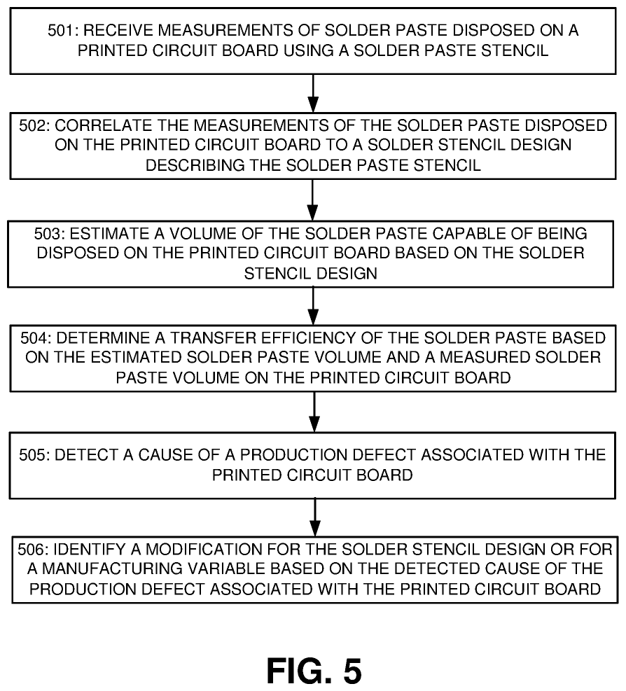

The solder stencil system 310 can include a printing analysis system 312 to utilize the inspection report 327 from the inspection equipment 324 to detect at least one potential printing-related defect in the manufacture of the printed circuit board assemblies and/or to identify a cause of defects identified during the manufacture of the printed circuit board as corresponding to solder paste printing. In some embodiments, the printing analysis system 312 can determine an expected outcome of the solder paste printing based on the solder stencil design 302 and possibly the printing parameters 303, and then compare the expected outcome to a measured outcome in the inspection report 327 to detect a potential printing-related defect or a cause of a defect identified in the subsequent manufacturing process. The defect can correspond to printing an incorrect amount of solder paste, printing the solder paste in an incorrect location or a location offset from expectation, printing solder paste unevenly across the printed circuit board 325 or a panel of multiple printed circuit boards, or the like. The cause of the printing-related defect can correspond to an issue with the solder stencil design, a type of solder paste being printed, a maintenance issue with the printing process, such as a blockage in the stencil, support for the printed circuit board 325, damaged equipment, a worn out stencil, or the like. The printing analysis system 312, in some embodiments, can utilize the detected printing-related defects to identify portions of the solder stencil design 302 that correspond to those defects. The printing analysis system 312 can generate a printing performance presentation 304 that can identify the expected outcome of the solder paste printing based on the solder stencil design 302, the measured outcome in the inspection report 327, and navigate to the portions of the solder stencil design 302 that correspond to detected printing-related defects, for example, allowing designers to view the designed apertures in the solder paste stencil 326. Embodiments of the printing analysis system 312 will be described below in greater detail with reference to FIG. 5.

FIG. 5 illustrates a flowchart showing an example implementation of a solder paste application with inspection-based feedback according to various embodiments. Referring to FIGS. 3 and 5, the printing analysis system 312 includes a design correlation system 313 that, in a block 501, can receive measurements of solder paste disposed on a printed circuit board 325 using the solder paste stencil 326. As discussed above, the inspection equipment 324 can measure the solder paste disposed on the printed circuit board 325 using the solder paste stencil 326 and include those measurements in the inspection report 327 provided to the design correlation system 313. In some embodiments, the design correlation system 313 can tag the inspection report 327 with an indicator of the corresponding solder stencil design 302 associated with the solder paste stencil 326 used to print the solder paste on the printed circuit board 325.

The design correlation system 313, in a block 502, can correlate the measurements of the solder paste disposed on the printed circuit board 325 to the solder stencil design 302 describing the solder paste stencil 326. In some embodiments, the inspection report 327 lists the measurements of the solder paste printed on the printed circuit board 325 with x-y coordinates corresponding to their location relative to the printed circuit board 325. The design correlation system 313 can map the x-y coordinates of the solder paste measurements in the inspection report 327 to a footprint of the solder stencil design 302 associated with the solder paste stencil 326. In some embodiments, the design correlation system 313 also can map the x-y coordinates of the solder paste measurements in the inspection report 327 to locations of pads in the printed circuit board design 301.

The printing analysis system 312 includes a printing expectation system 314 that, in a block 503, can estimate a volume of the solder paste capable of being disposed on the printed circuit board 325 based on the solder stencil design 326. In some embodiments, the printing expectation system 314 can utilize the size of the apertures of the solder paste stencil 326 described in the solder stencil design 326 and a thickness of the solder paste stencil 326 described in the solder stencil design 326 optionally along with one or more of the printing parameters 303, such as a type of solder paste used in the printing process, a print speed, a print pressure, a separation speed of the solder paste stencil 326 from the printed circuit board 325, or the like, to estimate a volume of solder paste to be disposed on the printed circuit board 325 during the solder paste printing process. The printing expectation system 313 can also determine expected locations on the printed circuit board 325, such as the pads and lands, for the solder paste to be disposed via the solder paste printing process.

The printing analysis system 312 includes a transfer efficiency system 315 that, in a block 504, can determine a transfer efficiency of the solder paste based on the estimated solder paste volume and a measured solder paste volume on the printed circuit board 325. In some embodiments, the transfer efficiency can correspond to a relative percentage of the expected volume of solder paste that was measured as being printed on the printed circuit board 325. The transfer efficiency system 315 also can determine differences in the locations of the solder paste printed on the printed circuit board 325 relative to expected locations for the solder paste on the printed circuit board 325. In some embodiments, the transfer efficiency system 315 can consolidate the determined differences into offset values, for example, a distance in an x-direction and a distance in a y-direction that solder paste printed on the printed circuit board 325 deviated from the expected locations on the printed circuit board 325 based on the solder stencil design 302. The transfer efficiency system 315 can aggregate the offset values across the printed circuit board 325, across a panel of multiple printed circuit boards being printed with solder paste, across multiple printed circuit boards over time printed with the solder paste stencil 326, by location on the printed circuit boards, by electronic component to be soldered using the printed solder paste, or the like.

The printing analysis system 312, in a block 505, can detect a cause of a production defect associated with the printed circuit board. In some embodiments, the printing analysis system 312 identify potential production defects based on the transfer efficiency of the solder paste, based on the offsets of the printing of the solder paste, based on other measurement information in the inspection report 327, or the like. For example, when the inspection report 327 indicates no or minimal solder paste was printed on a pad of the printed circuit board 325, such as if there was a blockage in the solder paste stencil 326, or indicates a large offset in the solder paste printing for the pad, the printing analysis system 312 can identify a potential production defect associated with that pad of the printed circuit board 325. In another example, when the inspection report 327 indicates excess solder paste was printed on a pad of the printed circuit board 325, such as if the aperture in the solder paste stencil 326 was too large, the printing analysis system 312 can identify a potential production defect associated with that pad of the printed circuit board 325. In some embodiments, the printing analysis system 312 can detect a change in how the solder paste printing equipment 323 prints the solder paste over time, for example, based on changes in the transfer efficiency or offsets as different printed circuit board 325 have been printed with solder paste. Because the inspection report 327 was mapped to the solder stencil design 302 and optionally the printed circuit board design 301, the printing analysis system 312 can associate the detected defects to specific apertures of the solder stencil design 302, to specific electronic components in the printed circuit board design 301, to printing characteristics by the solder paste printing equipment 323, or the like. As discussed above, the printing analysis system 312 can utilize this association between the detected defects and the specific apertures to alter the printing performance presentation 304 to navigate to the apertures associated with the detected defects, for example, to allow users to view the design of the apertures in the solder paste stencil 326.

The printing analysis system 312 includes a performance adjustment system 316 that, in a block 506, can identify a modification for the solder stencil design 302 or for a manufacturing variable based on the detected cause of the production defect associated with the printed circuit board 325. For example, the performance adjustment system 316 can utilize the transfer efficiency and/or the offsets to modify one or more apertures or a thickness of the solder stencil design 302 to adjust a volume or location of the solder paste printed on the printed circuit board 325. These modified apertures or a thickness of the solder stencil design 302 can be utilized by the solder stencil design system 311 as new real-production generated KPIs for subsequent design of solder paste stencils. The performance adjustment system 316 also can identify that a modification of a solder paste type, for example, having different solder ball sizing, can reduce or cure a solder paste variation type of production defect. The performance adjustment system 316 can identify a different stencil technology, such as a stainless steel stencil, a fine-grained stainless steel stencil, a nano-coated stencil, or the like, having apertures formed using one or more of laser cutting, etching, electro-formation, or the like, can reduce or cure a solder paste variation type of production defect. The performance adjustment system 316 can identify potential solder paste printing equipment 323 alterations to reduce or cure a production defect, such as changing a wore out solder paste stencil 326, altering support for the printed circuit board 325, unblocking the solder paste stencil 326, changing a solder paste application equipment, such as a squeegee, altering printing parameters 303, such as print speed, print pressure, separation speed of the solder paste stencil 326 form the printed circuit board 325, or the like.

The printing analysis system 312 can generate a printing performance presentation 304, which can identify locations of the pads in the printed circuit board design 301 to be printed with solder paste, locations of apertures described in the solder stencil design 302, and relative offsets associated with printed solder paste measure from the inspection report 327. The printing performance presentation 304 also can include expected solder paste volume per location, measure solder paste volume per location, and/or a transfer efficiency of printed solder paste per location. The printing performance presentation 304 can identify which of the locations of printed solder paste can correspond to a potential production defect, why those locations were considered a potential production defect, and identify causes associated with the potential production defect, such as due to the solder stencil design 302, the solder paste printed equipment 323, the solder paste stencil 326, or the like.

The system and apparatus described above may use dedicated processor systems, micro controllers, programmable logic devices, microprocessors, or any combination thereof, to perform some or all of the operations described herein. Some of the operations described above may be implemented in software and other operations may be implemented in hardware. Any of the operations, processes, and/or methods described herein may be performed by an apparatus, a device, and/or a system substantially similar to those as described herein and with reference to the illustrated figures.

The processing device may execute instructions or “code” stored in memory. The memory may store data as well. The processing device may include, but may not be limited to, an analog processor, a digital processor, a microprocessor, a multi-core processor, a processor array, a network processor, or the like. The processing device may be part of an integrated control system or system manager, or may be provided as a portable electronic device configured to interface with a networked system either locally or remotely via wireless transmission.

The processor memory may be integrated together with the processing device, for example RAM or FLASH memory disposed within an integrated circuit microprocessor or the like. In other examples, the memory may comprise an independent device, such as an external disk drive, a storage array, a portable FLASH key fob, or the like. The memory and processing device may be operatively coupled together, or in communication with each other, for example by an I/O port, a network connection, or the like, and the processing device may read a file stored on the memory. Associated memory may be “read only” by design (ROM) by virtue of permission settings, or not. Other examples of memory may include, but may not be limited to, WORM, EPROM, EEPROM, FLASH, or the like, which may be implemented in solid state semiconductor devices. Other memories may comprise moving parts, such as a known rotating disk drive. All such memories may be “machine-readable” and may be readable by a processing device.

Operating instructions or commands may be implemented or embodied in tangible forms of stored computer software (also known as “computer program” or “code”). Programs, or code, may be stored in a digital memory and may be read by the processing device. “Computer-readable storage medium” (or alternatively, “machine-readable storage medium”) may include all of the foregoing types of memory, as well as new technologies of the future, as long as the memory may be capable of storing digital information in the nature of a computer program or other data, at least temporarily, and as long at the stored information may be “read” by an appropriate processing device. The term “computer-readable” may not be limited to the historical usage of “computer” to imply a complete mainframe, mini-computer, desktop or even laptop computer. Rather, “computer-readable” may comprise storage medium that may be readable by a processor, a processing device, or any computing system. Such media may be any available media that may be locally and/or remotely accessible by a computer or a processor, and may include volatile and non-volatile media, and removable and non-removable media, or any combination thereof.

A program stored in a computer-readable storage medium may comprise a computer program product. For example, a storage medium may be used as a convenient means to store or transport a computer program. For the sake of convenience, the operations may be described as various interconnected or coupled functional blocks or diagrams. However, there may be cases where these functional blocks or diagrams may be equivalently aggregated into a single logic device, program or operation with unclear boundaries.

### Conclusion

While the application describes specific examples of carrying out embodiments of the invention, those skilled in the art will appreciate that there are numerous variations and permutations of the above described systems and techniques that fall within the spirit and scope of the invention as set forth in the appended claims. For example, while specific terminology has been employed above to refer to electronic design automation processes, it should be appreciated that various examples of the invention may be implemented using any desired combination of electronic design automation processes.

One of skill in the art will also recognize that the concepts taught herein can be tailored to a particular application in many other ways. In particular, those skilled in the art will recognize that the illustrated examples are but one of many alternative implementations that will become apparent upon reading this disclosure.

Although the specification may refer to “an”, “one”, “another”, or “some” example(s) in several locations, this does not necessarily mean that each such reference is to the same example(s), or that the feature only applies to a single example.

1. A method comprising:
receiving, by a computing system, measurements of solder paste disposed on a printed circuit board using a solder paste stencil;
correlating, by the computing system, the measurements of the solder paste disposed on the printed circuit board to a solder stencil design describing the solder paste stencil utilized during an application of the solder paste on the printed circuit board; and
detecting, by the computing system, a cause of a production defect associated with the printed circuit board based, at least in part, on the correlation of the measurements of the solder paste disposed on the printed circuit board to the solder stencil design.

2. The method of claim 1, wherein correlating the measurements of the solder paste disposed on the printed circuit board to the solder stencil design further comprises determining a transfer efficiency of the solder paste on the printed circuit board based, at least in part, on the solder paste stencil and the measurements of the solder paste disposed on the printed circuit board.

3. The method of claim 2, wherein determining the transfer efficiency of the solder paste on the printed circuit board further comprises:
estimating a volume of the solder paste capable of being disposed on the printed circuit board based, at least in part, on sizes of apertures in the solder stencil design; and
comparing the estimated volume of the solder paste capable of being disposed on the printed circuit board against a measured volume of the solder paste disposed on the printed circuit board to determine the transfer efficiency of the solder paste on the printed circuit board.

4. The method of claim 1, wherein detecting the cause of the production defect associated with the printed circuit board further comprises determining a configuration of one or more apertures in the solder stencil design corresponds to the cause of the production defect based, at least in part, on the correlation of the measurements of the solder paste disposed on the printed circuit board to the solder stencil design.

5. The method of claim 4, further comprising determining, by the computing system, one or more modifications for the solder stencil design based, at least in part, on the transfer efficiency of the solder paste on the printed circuit board.

6. The method of claim 1, wherein detecting the cause of the production defect associated with the printed circuit board further comprises determining a manufacturing variable corresponds to the cause of the production defect based, at least in part, on the correlation of the measurements of the solder paste disposed on the printed circuit board to the solder stencil design.

7. The method of claim 6, wherein the manufacturing variable includes including at least one of an offset between the solder stencil design and the printed circuit board, a support of the printed circuit board during the application of the solder paste to the printed circuit board, or one or more printing parameters during the application of the solder paste to the printed circuit board.

8. A system comprising:
a memory system configured to store computer-executable instructions; and
a computing system, in response to execution of the computer-executable instructions, is configured to:
receive measurements of solder paste disposed on a printed circuit board using a solder paste stencil;
correlate the measurements of the solder paste disposed on the printed circuit board to a solder stencil design describing the solder paste stencil utilized during an application of the solder paste on the printed circuit board; and
detect a cause of a production defect associated with the printed circuit board based, at least in part, on the correlation of the measurements of the solder paste disposed on the printed circuit board to the solder stencil design.

9. The system of claim 8, wherein the computing system, in response to execution of the computer-executable instructions, is further configured to correlate the measurements of the solder paste disposed on the printed circuit board to the solder stencil design by determining a transfer efficiency of the solder paste on the printed circuit board based, at least in part, on the solder paste stencil and the measurements of the solder paste disposed on the printed circuit board.

10. The system of claim 9, wherein the computing system, in response to execution of the computer-executable instructions, is further configured to determine the transfer efficiency of the solder paste on the printed circuit board by:
estimating a volume of the solder paste capable of being disposed on the printed circuit board based, at least in part, on sizes of apertures in the solder stencil design; and
comparing the estimated volume of the solder paste capable of being disposed on the printed circuit board against a measured volume of the solder paste disposed on the printed circuit board to determine the transfer efficiency of the solder paste on the printed circuit board.

11. The system of claim 8, wherein the computing system, in response to execution of the computer-executable instructions, is further configured to detect the cause of the production defect associated with the printed circuit board by determining a configuration of one or more apertures in the solder stencil design corresponds to the cause of the production defect based, at least in part, on the correlation of the measurements of the solder paste disposed on the printed circuit board to the solder stencil design.

12. The system of claim 11, wherein the computing system, in response to execution of the computer-executable instructions, is further configured to determine one or more modifications for the solder stencil design based, at least in part, on the transfer efficiency of the solder paste on the printed circuit board.

13. The system of claim 8, wherein the computing system, in response to execution of the computer-executable instructions, is further configured to detect the cause of the production defect associated with the printed circuit board by determining a manufacturing variable corresponds to the cause of the production defect based, at least in part, on the correlation of the measurements of the solder paste disposed on the printed circuit board to the solder stencil design.

14. An apparatus comprising at least one computer-readable memory device storing instructions configured to cause one or more processing devices to perform operations comprising:
receiving measurements of solder paste disposed on a printed circuit board using a solder paste stencil;
correlating the measurements of the solder paste disposed on the printed circuit board to a solder stencil design describing the solder paste stencil utilized during an application of the solder paste on the printed circuit board; and
detecting a cause of a production defect associated with the printed circuit board based, at least in part, on the correlation of the measurements of the solder paste disposed on the printed circuit board to the solder stencil design.

15. The apparatus of claim 14, wherein correlating the measurements of the solder paste disposed on the printed circuit board to the solder stencil design further comprises determining a transfer efficiency of the solder paste on the printed circuit board based, at least in part, on the solder paste stencil and the measurements of the solder paste disposed on the printed circuit board.

16. The apparatus of claim 15, wherein determining the transfer efficiency of the solder paste on the printed circuit board further comprises:
estimating a volume of the solder paste capable of being disposed on the printed circuit board based, at least in part, on sizes of apertures in the solder stencil design; and
comparing the estimated volume of the solder paste capable of being disposed on the printed circuit board against a measured volume of the solder paste disposed on the printed circuit board to determine the transfer efficiency of the solder paste on the printed circuit board.

17. The apparatus of claim 14, wherein detecting the cause of the production defect associated with the printed circuit board further comprises determining a configuration of one or more apertures in the solder stencil design corresponds to the cause of the production defect based, at least in part, on the correlation of the measurements of the solder paste disposed on the printed circuit board to the solder stencil design.

18. The apparatus of claim 17, wherein the instructions are configured to cause the one or more processing devices to perform operations further comprising determining one or more modifications for the solder stencil design based, at least in part, on the transfer efficiency of the solder paste on the printed circuit board.

19. The apparatus of claim 14, wherein detecting the cause of the production defect associated with the printed circuit board further comprises determining a manufacturing variable corresponds to the cause of the production defect based, at least in part, on the correlation of the measurements of the solder paste disposed on the printed circuit board to the solder stencil design.

20. The apparatus of claim 19, wherein the manufacturing variable includes including at least one of an offset between the solder stencil design and the printed circuit board, a support of the printed circuit board during the application of the solder paste to the printed circuit board, or one or more printing parameters during the application of the solder paste to the printed circuit board.
